(19) United States
(12) Patent Application Publication
(10) Pub. No.: US 2024/0084079 A1
(43) Pub. Date: Mar. 14, 2024

(54) METHOD FOR THE PRODUCTION OF METAL-ORGANIC FRAMEWORK COATED LIGHT EMITTED DIODE

(71) Applicant: CITY UNIVERSITY OF HONG KONG, Kowloon (HK)

(72) Inventors: Thuc Hue LY, Kowloon (HK); Ping MAN, Kowloon (HK); Ka Ho LEUNG, Kowloon (HK)

(21) Appl. No.: 17/940,934

(22) Filed: Sep. 8, 2022

(51) Int. Cl. C08G 83/00; B82Y 30/00; B82Y 40/00; H01L 51/50

(52) U.S. Cl. CPC C08G 83/008; B82Y 30/00; B82Y 40/00; H01L 51/502

(57) ABSTRACT

Disclosed herein are processes for producing metal-organic framework (MOF) materials (e.g., ZIF-67), as well as MOF-coated light emitted diodes (LEDs). The process for producing ZIF-67 nanoparticles includes (a) mixing a solution of cobalt(II) hexahydrate and a solution of 2-methylimiazole to give a first mixture solution; and (b) let the first mixture solution stand for a sufficient period of time to allow the growth of the ZIF-67 nanoparticles. The process for producing a ZIF-67-coated light emitted diode (LED) includes (i) dispersing the ZIF-67 nanoparticles in a poly (methyl methacrylate) (PMMA) solution to form a ZIF-67@PMMA slurry; and (ii) applying the ZIF-67@PMMA slurry onto the surface of an LED in a dropwise manner to give the ZIF-67@PMMA-coated LED.

### BACKGROUND OF THE INVENTION

### 1. Field of the Invention

The present invention relates to methods of producing tunable light emitted diode (LED), particularly, the metal-organic framework (MOF)-coated LED.

### 2. Description of Related Art

LED is invented by scientists with numerous of advantages, including higher energy conversion rate, longer lifetime and tunable color compared to traditional tungsten wire light bulb, it replaces most of them and become a majority use in our society. Yet, current commercial LEDs often involves the use of expensive rare-earth metal compounds as the luminescent material, including In, Al and Ga, these compounds limited the cost of LED and its popularity as well, as a result, researchers focus their research on finding materials to replace the rare-earth material, one of the examples would be organic LED (OLED), in which organic molecules are used as a luminescent layer. Apart from OLED, metal-organic framework (MOF) family has also attracted many researchers for some of MOF members also contains luminescent property.

MOF materials are crystal compounds consisting of metal ions coordinated to rigid organic molecules to form novel hybrid materials that are highly porous. Each MOF material displays the advantages of simple large-scale production (e.g., STY of MOF Mil-160 (Al) ˜38 kg m-3 day-1), low cost (e.g., the MOF Mil-160 (Al)<$10 per kg) and structure variability. Some of the MOF materials (˜11%) contain electroluminescence/photoluminescence properties, in which the electroluminescence property can be packaged into the LED chip, and its photoluminescence property also can be used as the coating of the current LED for color adjustment. These luminescence properties can be elaborately designed and tuned by selecting metal nodes and organic ligands. In addition, due to the unique pore structure of MOF, organic fluorescent dyes can also be encapsulated to systematically regulate the emission color and quality. So far, many reported MOF-based white LEDs showed broad application prospects with a color rendering index (CRI) value above 80, and a luminous efficiency over 200 lm·W⁻¹.

Based on various properties of MOF, in this project, we develop a new type of LED by MOF with high color-rendering index, which previous study had shown MOF-based LED could give comparable rendering region of the emitted light compare with commercial product. It shows that the color quality, luminous efficiency, and long-term stability would be regulated by introduced ligands and light/laser source and the polymer-coating. We expect the controlled modulation on the MOF can be applied to regulate and adjust the emission for high performance and low-cost LED. Moreover, such novel MOF-based tunable LEDs strategy can be universal for other fluorescence MOF to promote more application in multi-functional modular devices.

### SUMMARY

Embodiments of the present disclosure relate to methods of producing MOF materials, particularly, zeolitic imidazolate framework-67 (ZIF-67) nanoparticles; and methods of producing MOF material-coated LEDs.

Accordingly, the first objective of the present disclosure therefore is to provide a method of producing ZIF-67 nanoparticles. The method includes steps of,
(a) mixing a solution of cobalt(II) hexahydrate and a solution of 2-methylimiazole to give a first mixture solution; and
(b) let the first mixture solution stand for a sufficient period of time to allow the growth of the ZIF-67 nanoparticles.

According to embodiments of the present disclosure, the ZIF-67 nanoparticles are collected by filtration or centrifugation.

Alternatively or optionally, the method further includes drying the collected ZIF-67 nanoparticles at 60° C. for 12 to 24 hours.

According to embodiments of the present disclosure, in the step (a), the solution of cobalt(II) hexahydrate and the solution of 2-methylimiazole are respectively produced by dissolving cobalt(II) hexahydrate and 2-methylimiazole in methanol, water or a combination thereof.

According to embodiments of the present disclosure, in the step (a), the solution of cobalt(II) hexahydrate and the solution of 2-methylimiazole are mixed in a molar ratio of 1:3.

The second objective of the present disclosure therefore is to provide a method of producing a ZIF-67-coated light emitted diode (LED). The method includes steps of,
(a) dispersing the ZIF-67 nanoparticles produced by the method described above in a poly (methyl methacrylate) (PMMA) solution to form a ZIF-67@PMMA slurry; and
(b) applying the ZIF-67@PMMA slurry onto the surface of an LED in a dropwise manner to give the ZIF-67@PMMA-coated LED.

According to embodiments of the present disclosure, step (b) is repeated 2 to 10 times until the surface of the LED is completely and evenly coated, and the color of the LED becomes purple.

According to embodiments of the present disclosure, in the step (a), the ZIF-67 nanoparticles is dispersed in the PMMA solution in a ratio of about 1 mg of the ZIF-67 nanoparticles in 1 mL of PMMA solution; and the PMMA solution is kept at the temperature of about 150° C.

Alternatively or optionally, the method further includes drying the ZIF-67@PMMA-coated LED of step (b) at 180° C.

Other and further embodiments of the present disclosure are described in more detail below.

### BRIEF DESCRIPTION OF THE DRAWINGS

The disclosure will become more fully understood from the detailed description and the drawings given herein below for illustration only, and thus does not limit the disclosure, wherein:

FIG. 1 is the SEM image of ZIF-67 nanoparticles prepared in accordance with one embodiment of the present disclosure;

FIG. 2 is the X-ray diffraction spectrum of the ZIF-67 nanoparticles of FIG. 1;

FIG. 3 is the Raman spectrum of the ZIF-67 nanoparticles of FIG. 1; and

FIG. 4 is Raman spectrum of the ZIF-67@PMMA film prepared in accordance with one embodiment of the present disclosure.

### DETAILED DESCRIPTION

Detailed descriptions and technical contents of the present disclosure are illustrated below in conjunction with the accompanying drawings. However, it is to be understood that the descriptions and the accompanying drawings disclosed herein are merely illustrative and exemplary and not intended to limit the scope of the present disclosure.

The present disclosure provides a novel process for the production of MOFs suitable for large-scale production of tunable LEDs. Particularly, embodiments of the present disclosure include improved methods of producing ZIF-67 nanoparticles and LEDs coated with an electroluminescent layer comprising the same. Methods in accordance with embodiments of the present disclosure are advantageously simple, and easy-to-use, thus are suitable for producing tunable LED in large scale.

1. ZIF-67 Nanoparticles

The first aspect of the present disclosure is to provide a method of producing ZIF-67 nanoparticles. The method is characterized in having steps of,
(a) mixing a solution of cobalt(II) hexahydrate and a solution of 2-methylimiazole to give a first mixture solution; and
(b) let the first mixture solution stand for a sufficient period of time to allow the growth of the ZIF-67 nanoparticles.

Prior to the commencement of the present method, sufficient amounts of cobalt(II) hexahydrate and 2-methylimiazole are respectively dissolved in a solvent to give the solution of cobalt(II) hexahydrate and the solution of 2-methylimiazole. Examples of the solvent suitable for use in the present method include, but are not limited to, methanol, water, and a combination of water and methanol. In some embodiments, the cobalt(II) hexahydrate and the 2-methylimiazole are respectively dissolved in water. In other embodiments, the cobalt(II) hexahydrate and the 2-methylimiazole are respectively dissolved in methanol. In further embodiments, the cobalt(II) hexahydrate and the 2-methylimiazole are respectively dissolved in a solution composed of water and methanol.

The thus produced cobalt(II) hexahydrate solution and the 2-methylimiazole solution are then mixed to give a mixture solution (step (a)), in which the cobalt(II) hexahydrate and the 2-methylimiazole are respectively present in a molar ratio of 1:3 in the mixture solution.

The mixture solution is let stand for a sufficient period of time (e.g., 1 to 10 minutes) to allow the growth of the ZIF-67 nanoparticles (step (b)). Preferably, the mixture solution is let stand for about 5 minutes to allow the growth of the ZIF-67 nanoparticles. The thus produced ZIF-67 nanoparticles are then collected by filtration or centrifugation. In some embodiments, the mixture solution is centrifuged at 10,000 rpm for 10 minutes to harvest the ZIF-67 nanoparticles. Preferably, the centrifugation is repeated for at least 3 times, such as 3, 4, and 5 times.

Alternatively or additionally, the collected ZIF-67 nanoparticles is dried in an oven to remove any residual solvent. In preferred embodiments, the collected ZIF-67 nanoparticles are dried at 60° C. for at least 12 hours, such as 12, 13, 14, 15, 16, 17, 18, 19, 20, 21, 22, 23, and 24 hours. According to embodiments of the present disclosure, the dried ZIF-67 nanoparticles are in the form of purple powders, and emit pink light upon excitation by a monowavelength light of 633 nm.

2. MOF-Coated Light Emitted Diode (LED)

The ZIF-67 nanoparticles produced by the present method are MOF materials suitable for the manufacture of tunable LEDs. Accordingly, the second objective of the present disclosure relates to a method of producing a MOF-coated LED. The method includes steps of,
(a) dispersing the ZIF-67 nanoparticles produced by the method described above in a poly (methyl methacrylate) (PMMA) solution to form a ZIF-67@PMMA slurry; and
(b) applying the ZIF-67@PMMA slurry onto the surface of an LED in a dropwise manner to give the ZIF-67@PMMA-coated LED.

According to embodiments of the present disclosure, in the step (a), the ZIF-67 nanoparticles prepared by the method described above is dispersed in the PMMA solution in a concentration of about 1 mg ZIF-67 per 1 mL PMMA solution; and the PMMA solution is kept at a temperature of about 150° C.

The thus produced ZIF-67@PMMA slurry is applied dropwisely into the surface of an LED

Preferably, step (b) may be repeated 2 to 10 times (e.g., 2, 3, 4, 5, 6, 7, 8, 9 and 10 times) until the surface of the LED is completely and evenly coated, and the color of the LED becomes purple.

Alternatively or optionally, the method further includes drying the ZIF-67@PMMA-coated LED of step (b) at 180° C. The thus produced LED, when luminated with a voltage from 2V to 3V, exhibits a remarkable color change, as compared to that of a controlled LED (i.e., the LED that is not coated with the present ZIF-67@PMMA).

Throughout the description and claims, “comprising” and “including” are interchangeably used, and are not intended to exclude other technical features, additives, components and steps. Additional objects, advantages and features of the invention will become apparent to those skilled in the art upon examination of the description or may be learned by practice of the invention.

### EXAMPLES

The following examples are provided by way of illustration, and are not intended to be limiting of the present invention.

### Example 1: Preparation and Characterization of ZIF-67 Nanoparticles

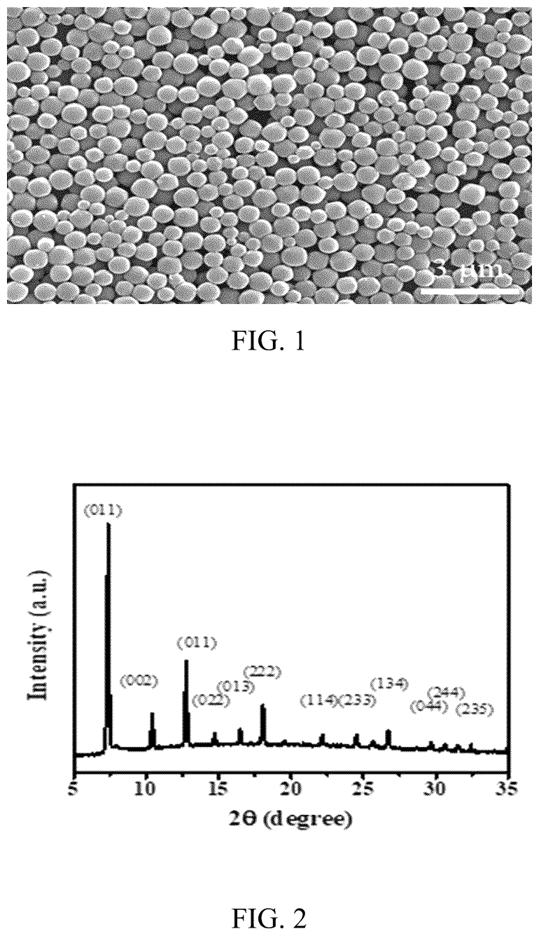

Weigh and dissolve 232.8 mg of cobalt(II) nitrate hexahydrate and 199 mg of 2-methylimidazole to 10 mL of methanol respectively, both solutions were stirred 15 mins to make sure all reactants are well dissolved. Two solutions are then mixed and stirred by a magnetic stir bar for 1 minute to ensure reactants are mixed well, the solution was then left for 5 minutes to allow the growth of ZIF-67 nanoparticles. Then, the solution was centrifuged to collect the participate, followed by three times of washing by methanol and dried under 60° C. for 24 hours to ensure all solvent was removed. The thus produced purple powders were then analyzed by Scanning Electron Microscope (SEM), X-ray diffraction and Raman spectroscopy. Results are shown in FIGS. 1 to 3.

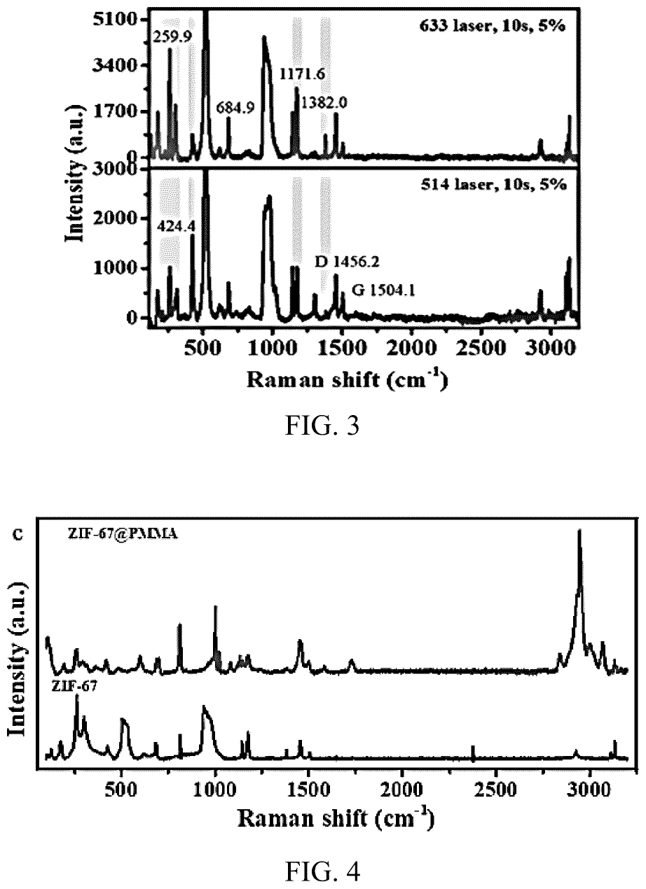

The SEM photograph indicated that the product was in decahedral like structure (FIG. 1), the X-ray diffraction pattern (FIG. 2) and Raman spectrum (FIG. 3) further confirmed that the obtained product was ZIF-67, in which the Raman shift at 161.9 and 178.8 cm-1 were attributed to the N—Co—N deformation vi-vibration modes. Notably, ZIF-67 solution showed pink light emitting under the excitation of 633 nm laser (data not shown).

### Example 2: Preparation and Characterization of ZIF-67@PMMA-Coated LED

2.1 ZIF-67@PMMA

The dried ZIF-67 nanoparticles of Example 1 (10 mg) were dispersed into 10 mL of C4 PMMA solution, the solution was stirred to ensure all nanoparticles were evenly distributed. The thus formed ZIF-67@PMMA slurry easily solidified into a film, and the Raman spectrum (FIG. 4) confirmed the signal of ZIF-67 and PMMA in the slurry, an indication that the ZIF-67 nanoparticles were stable in PMMA solution.

2.2 ZIF-67@PMMA-Coated LED

To fabricate MOF-coated LED, the ZIF-67@PMMA solution of Example 2.1 was first coated on a hot plane (150° C.), then was applied onto the surface of a commercial yellow LED shell (10 μL each) in a dropwise manner, and the thus coated LED was placed on a hot plane at about 180° C. The coating process was repeated several times until the color of LED became purple and the surface of LED became harmony.

The fabricated ZIF-67@PMMA-coated LED showed a pale red light after coating, an indication that a red shift had occurred with the coating of ZIF-67@PMMA.

Taken together, the present disclosure provides a means for easily production of tunable LED in large-scale

It will be understood that the above description of embodiments is given by way of example only and that various modifications may be made by those with ordinary skill in the art. The above specification, examples and data provide a complete description of the structure and use of exemplary embodiments of the invention. Although various embodiments of the invention have been described above with a certain degree of particularity, or with reference to one or more individual embodiments, those with ordinary skill in the art could make numerous alterations to the disclosed embodiments without departing from the spirit or scope of the present disclosure.

What is claimed is:

1. A method for producing zeolitic imidazolate framework-67 (ZIF-67) nanoparticles, comprising:
(a) mixing a solution of cobalt(II) hexahydrate and a solution of 2-methylimiazole to give a first mixture solution; and
(b) let the first mixture solution stand for a sufficient period of time to allow the growth of the ZIF-67 nanoparticles.

2. The method of claim 1, wherein ZIF-67 nanoparticles are collected by filtration or centrifugation.

3. The method of claim 2, further comprising drying the collected ZIF-67 nanoparticles at 60° C. for 12 to 24 hours.

4. The method of claim 1, wherein in the step (a),
the solution of cobalt(II) hexahydrate and the solution of 2-methylimiazole are respectively produced by dissolving cobalt(II) hexahydrate and 2-methylimiazole in a solvent that is any one of methanol, water or a combination thereof, and
the solution of cobalt(II) hexahydrate and the solution of 2-methylimiazole are mixed in a molar ratio of 1:3.

5. A method of producing a ZIF-67-coated light emitted diode (LED) comprising,
(a) dispersing the ZIF-67 nanoparticles of claim 1 in a poly (methyl methacrylate) (PMMA) solution to form a ZIF-67@PMMA slurry; and
(b) applying the ZIF-67@PMMA slurry onto the surface of an LED in a dropwise manner to give the ZIF-67@PMMA-coated LED.

6. The method of claim 5, wherein in the step (a),
the ZIF-67 nanoparticles of claim 1 is dispersed in the PMMA solution in a concentration of about 1 mg of the ZIF-67 nanoparticles per 1 mL of the PMMA solution; and
the PMMA solution is kept at the temperature of about 150° C.

7. The method of claim 5, further comprising repeating both the steps (a) and (b) until the surface of the LED is completely and evenly coated, and the color of the LED becomes purple.

8. The method of claim 7, further comprising drying the ZIF-67@PMMA-coated LED of step (b) at 180° C.
